(19) United States
(12) Patent Application Publication
(10) Pub. No.: US 2025/0221190 A1
(43) Pub. Date: Jul. 3, 2025

(54) DISPLAY PANEL

(71) Applicants: Hefei Visionox Technology Co., Ltd., Hefei (CN); KunShan Go-Visionox Opto-Electronics Co., Ltd, Kunshan (CN)

(72) Inventors: Zhiwei ZHOU, Hefei (CN); Jinfang ZHANG, Hefei (CN); Lu ZHANG, Hefei (CN)

(73) Assignees: Hefei Visionox Technology Co., Ltd., Hefei (CN); KunShan Go-Visionox Opto-Electronics Co., Ltd, Kunshan (CN)

(21) Appl. No.: 18/744,853

(22) Filed: Jun. 17, 2024

(30) Foreign Application Priority Data
Jan. 2, 2024 (CN) 202410005834.5

(51) Int. Cl. H10K 59/131; H10K 59/122; H10K 59/40

(52) U.S. Cl. CPC H10K 59/131; H10K 59/122; H10K 59/40

(57) ABSTRACT

A display panel and a display apparatus. The display panel includes: a substrate; a light-transmitting conductive layer arranged on one side of the substrate; an insulating protective layer arranged on a side of the light-transmitting conductive layer facing away from the substrate, a first opening and a communication hole being arranged through the insulating protective layer; an isolation structure arranged on a side of the insulating protective layer facing away from the substrate, the isolation structure enclosing and forming an isolation opening and a first light-transmitting opening; and a light-emitting layer including a light-emitting unit located in the isolation opening; wherein an orthographic projection of the first light-transmitting opening on the substrate at least partially overlaps with an orthographic projection of the light-transmitting conductive layer on the substrate, the isolation structure and the light-transmitting conductive layer are via connected through the communication hole.

### CROSS REFERENCE TO RELATED APPLICATION

The present application claims priority to Chinese Patent Application No. 202410005834.5 filed on Jan. 2, 2024, and titled “DISPLAY PANEL AND DISPLAY APPARATUS”, which is incorporated herein by reference in its entirety.

### TECHNICAL FIELD

The present application relates to the technical field of display devices, and in particular, to a display panel and a display apparatus.

### BACKGROUND

An organic light emitting display (OLED) and a flat display apparatus based on a light emitting diode (LED) technology are widely used in various consumer electronic products such as mobile phones, TVs, notebook computers, and desktop computers due to advantages such as high image quality, power saving, a thin body, and a wide range of applications, becoming the mainstream in display apparatuses.

However, operational performance of current OLED display products needs to be improved.

### SUMMARY

Embodiments of the present application provide a display panel and a display apparatus, intended to improve process performance of the display panel.

In a first aspect of the present application, an embodiment provides a display panel, including: a substrate; a light-transmitting conductive layer arranged on one side of the substrate; an insulating protective layer arranged on a side of the light-transmitting conductive layer facing away from the substrate, a first opening and a communication hole being arranged through the insulating protective layer; an isolation structure arranged on a side of the insulating protective layer facing away from the substrate, the isolation structure enclosing and forming an isolation opening and a first light-transmitting opening; and a light-emitting layer including a light-emitting unit located in the isolation opening; wherein an orthographic projection of the first light-transmitting opening on the substrate is located within an orthographic projection of the light-transmitting conductive layer on the substrate, and the orthographic projection of the first light-transmitting opening on the substrate is located within a range of an orthographic projection of the insulating protective layer on the substrate.

In the first aspect of the present application, a display panel is further provided, including: a substrate; a light-transmitting conductive layer arranged on one side of the substrate, the light-transmitting conductive layer having a mesh structure and having a second opening; an isolation structure arranged on a side of the light-transmitting conductive layer facing away from the substrate, the isolation structure enclosing and forming an isolation opening and a first light-transmitting opening, and an orthographic projection of the isolation opening on the substrate being located within an orthographic projection of the second opening on the substrate; and a light-emitting layer including a light-emitting unit located in the isolation opening; wherein an orthographic projection of the first light-transmitting opening on the substrate is located within an orthographic projection of the light-transmitting conductive layer on the substrate, and the isolation structure is electrically connected to the light-transmitting conductive layer.

In the first aspect of the present application, a display panel is further provided, including: a substrate; a light-transmitting conductive layer arranged on one side of the substrate and including a plurality of light-transmitting conductive portions arranged at intervals; an isolation structure arranged on a side of the light-transmitting conductive layer facing away from the substrate, the isolation structure enclosing and forming an isolation opening and a first light-transmitting opening; and a light-emitting layer including a light-emitting unit located in the isolation opening; wherein an orthographic projection of the first light-transmitting opening on the substrate is located within an orthographic projection of the light-transmitting conductive portion on the substrate, and the isolation structure is electrically connected to the light-transmitting conductive portion.

In a second aspect of the present application, an embodiment further provides a display apparatus, including the display panel according to any one of the embodiments in the first aspect.

In the display panel according to the embodiments of the present application, the display panel includes a substrate and a light-transmitting conductive layer, an insulating protective layer, and an isolation structure that are arranged on the substrate, and the insulating protective layer arranged on a side of the light-transmitting conductive layer facing away from the substrate can protect the light-transmitting conductive layer. The insulating protective layer is provided with the first opening, so that the insulating protective layer may not affect light emission of the display panel. The isolation structure encloses and forms an isolation opening and a first light-transmitting opening. The isolation opening is configured to accommodate a light-emitting unit. The first light-transmitting opening is configured to improve light transmittance of the display panel. Due to the existence of the first light-transmitting opening, a touch electrode subsequently manufactured may produce an electric field effect and parasitic capacitance between the first light-transmitting opening and wires in the substrate. The corresponding arrangement of the light-transmitting conductive layer and the first light-transmitting opening can ameliorate the above parasitic capacitance. Therefore, according to the embodiments of the present application, through the arrangement of the light-transmitting conductive layer, the parasitic capacitance in the display panel can be ameliorated, signal transmission of the touch electrode can be improved, and process performance of the display panel can be improved.

### BRIEF DESCRIPTION OF THE DRAWINGS

Other features, objectives, and advantages of the present application will become more apparent upon reading the following detailed description of non-limiting embodiments with reference to the accompanying drawings. Same or similar reference numerals indicate same or similar features.

FIG. 1 is a schematic structural diagram of a display panel according to an embodiment of the present application;

FIG. 2 is a sectional view of A-A in FIG. 1 in an example;

FIG. 3 is a sectional view of A-A in FIG. 1 in another example;

FIG. 4 is a schematic structural diagram of the display panel according to another embodiment of the present application;

FIG. 5 is a partial sectional view of the display panel according to another embodiment of the present application;

FIG. 6 is a schematic structural diagram of the display panel according to yet another embodiment of the present application;

FIG. 7 is a schematic structural diagram of the display panel according to still another embodiment of the present application;

FIG. 8 is a schematic structural diagram of the display panel according to a further embodiment of the present application;

FIG. 9 is a schematic structural diagram of the display panel according to a further embodiment of the present application;

FIG. 10 is a partial sectional view of the display panel according to yet another embodiment of the present application; and

FIG. 11 is a schematic flowchart of a manufacturing method for a display panel according to an embodiment of the present application.

### REFERENCE SIGNS

10: display panel;
100: substrate; 110: first electrode layer; 111: first electrode; 120: signal line;
200: light-transmitting conductive layer; 201: light-transmitting conductive portion; 210: second opening; 220: first conductive portion; 230: second conductive portion; 231: first segment; 232: second segment; 240: auxiliary conductive layer; 250: shielding portion; 260: connecting portion;
300: insulating protective layer; 310: first opening; 320: communication hole; 321: first communication hole; 322: second communication hole; 323: third communication hole;
400: isolation structure; 401: first sublayer; 402: second sublayer; 403: third sublayer; 410: isolation opening; 420: first light-transmitting opening; 430: second light-transmitting opening;
500: pixel defining layer; 510: pixel defining portion; 520: pixel opening; 530: pad portion;
600: light-emitting unit; 601: first pixel column; 602: second pixel column; 610: first light-emitting unit; 620: second light-emitting unit; 630: third light-emitting unit;
700: dam;
800: second electrode layer; 810: second electrode;
900: touch electrode;
AA: display region; ZA: main display region; TA: light-transmitting display region; NA: non-display region;
X: first direction; Y: second direction.

### DETAILED DESCRIPTION

Features and exemplary embodiments in various aspects of the present application will be described in detail below. In the following detailed description, numerous specific details are set forth in order to provide a thorough understanding of the present application. However, it will be apparent to those skilled in the art that the present application can be implemented without some of these specific details. The following description of the embodiments is merely to provide a better understanding of the present application by illustrating the examples of the present application. In the drawings and the following description, at least part of well-known structures and technologies are not shown in order to avoid unnecessarily obscuring the present application. Further, for clarity, sizes of part of the structures may be exaggerated. Furthermore, the features, structures, or characteristics described below may be combined in any suitable manner in one or more embodiments.

In the description of the present application, it should be noted that, unless otherwise stated, “a plurality” means two or more; the orientation or positional relationship indicated by the terms “upper”, “lower”, “left”, “right”, “inner”, “outer”, and the like is merely for the purpose of describing the present application and simplifying the description, and is not intended to indicate or imply that the apparatus or element referred to has a particular orientation, is constructed and operated in a particular orientation, and therefore cannot be understood to be a limitation on the present application. Moreover, the terms “first”, “second”, and the like are for descriptive purposes only and cannot be construed as indicating or implying relative importance.

The terms of orientation in the following description are all directions shown in the drawings and are not intended to limit specific structures of the present application. In the description of the present application, it is to be further noted that unless specifically stated and limited, the terms “mount” and “connect” should be understood in a broad sense, such as, a fixed connection, a detachable connection, or an integral connection; or a direct connection, or an indirect connection. For those of ordinary skill in the art, the specific meanings of the above terms in the present application may be understood depending on specific situations.

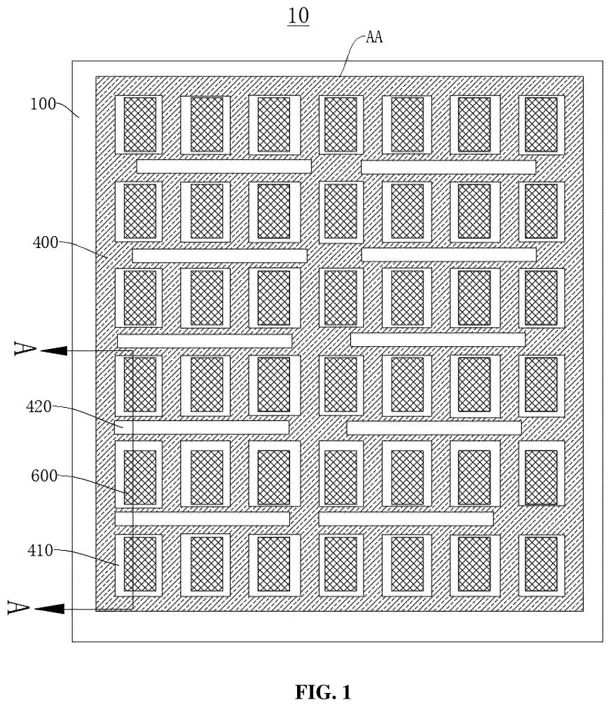

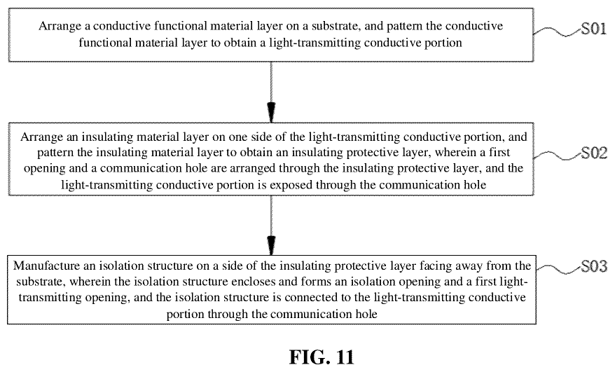

For better understanding of the present application, a display panel and a display apparatus according to embodiments of the present application will be described in detail below with reference to FIG. 1 to FIG. 11.

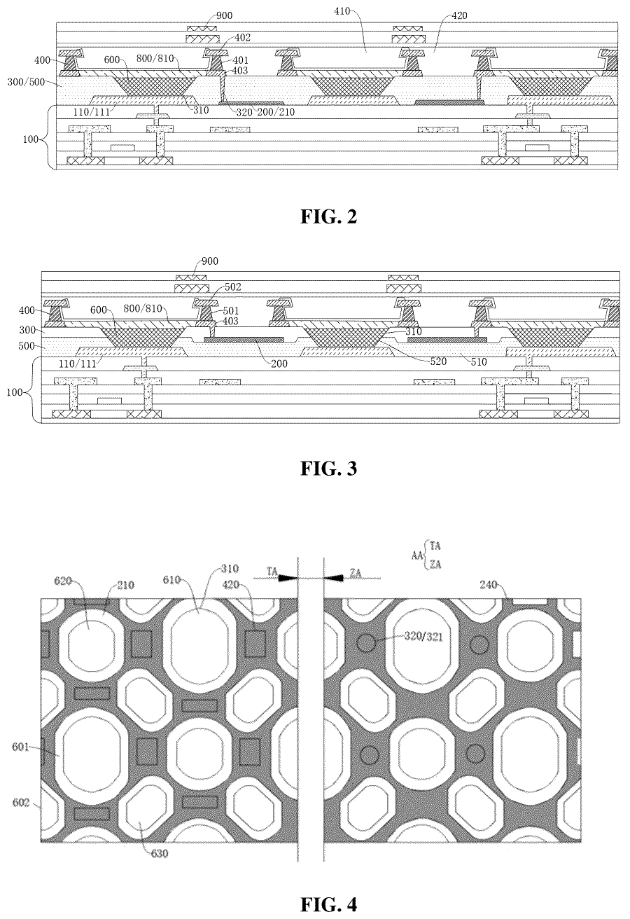

FIG. 1 is a schematic structural diagram of a display panel 10 according to an embodiment of the present application; and FIG. 2 is a sectional view of A-A in FIG. 1 in an example.

As shown in FIG. 1 and FIG. 2, in a first aspect of the present application, an embodiment provides a display panel 10. The display panel 10 includes a substrate 100, a light-transmitting conductive layer 200, an insulating protective layer 300, an isolation structure 400, and a light-emitting layer. The light-transmitting conductive layer 200 is arranged on one side of the substrate 100. The insulating protective layer 300 is arranged on a side of the light-transmitting conductive layer 200 facing away from the substrate 100, and a first opening 310 is arranged through the insulating protective layer 300. The isolation structure 400 is arranged on a side of the insulating protective layer 300 facing away from the substrate 100, and the isolation structure 400 encloses and forms an isolation opening 410 and a first light-transmitting opening 420. The light-emitting layer includes a light-emitting unit 600 located in the isolation opening 410. An orthographic projection of the first light-transmitting opening 420 on the substrate 100 is located within an orthographic projection of the light-transmitting conductive layer 200 on the substrate 100, and the orthographic projection of the first light-transmitting opening 420 on the substrate 100 is located within a range of an orthographic projection of the insulating protective layer 300 on the substrate 100.

In the display panel 10 according to the embodiments of the present application, the display panel 10 includes a substrate 100 and a light-transmitting conductive layer 200, an insulating protective layer 300, and an isolation structure 400 that are arranged on the substrate 100, and the insulating protective layer 300 arranged on a side of the light-transmitting conductive layer 200 facing away from the substrate 100 can protect the light-transmitting conductive layer 200. The isolation structure 400 encloses and forms an isolation opening 410 and a first light-transmitting opening 420. The isolation opening 410 is configured to accommodate a light-emitting unit 600. The first light-transmitting opening 420 is configured to improve light transmittance of the display panel 10. Due to the existence of the first light-transmitting opening 420, a touch electrode 900 subsequently manufactured may produce an electric field effect and parasitic capacitance between the first light-transmitting opening 420 and wires in the substrate 100. The corresponding arrangement of the light-transmitting conductive layer 200 and the first light-transmitting opening 420 can ameliorate the above parasitic capacitance. Therefore, according to the embodiments of the present application, through the arrangement of the light-transmitting conductive layer 200, the parasitic capacitance in the display panel 10 can be ameliorated, signal transmission of the touch electrode 900 can be improved, and process performance of the display panel 10 can be improved.

Optionally, the light-transmitting conductive layer 200 is electrically connected to the isolation structure 400. Optionally, the light-transmitting conductive layer 200 and the isolation structure 400 may be electrically connected by connecting the light-transmitting conductive layer 200 and the isolation structure 400 to a power signal line in a bezel region of the display panel respectively, so that the light-transmitting conductive layer 200 and the isolation structure 400 have a same fixed potential.

The light-transmitting conductive layer 200 and the isolation structure 400 may alternatively be electrically connected by providing a communication hole 320 in the insulating protective layer 300, and the isolation structure 400 is via connected to the light-transmitting conductive layer 200 through the communication hole 320.

Optionally, an orthographic projection of the isolation opening 410 on the substrate 100 at least partially overlaps with an orthographic projection of the first opening 310 on the substrate 100, so that the light-emitting unit 600 can emit light through the first opening 310 and the isolation opening 410 at the same time. Optionally, the orthographic projection of the isolation opening 410 on the substrate 100 is located within the orthographic projection of the first opening 310 on the substrate 100, so as to increase an area of a light-emitting opening and improve a display effect of the display panel 10.

Optionally, a first electrode layer 110 may be arranged on the substrate 100, the first electrode layer 110 includes a plurality of first electrodes 111 arranged at intervals, and an orthographic projection of each first electrode 111 on the substrate 100 at least partially overlaps with the orthographic projection of the first opening 310 on the substrate 100, so that the first electrode 111 can drive the light-emitting unit 600 located in the first opening 310 to emit light.

Optionally, the insulating protective layer 300 is located on a side of the first electrode layer 110 facing away from the substrate 100, and the insulating protective layer 300 partially covers a side of the first electrode 111 facing away from the substrate 100, so that the first electrode 111 can be exposed through the first opening 310.

The substrate 100 is arranged in a variety of manners. The substrate 100 may include a base and a first conductive layer, a second conductive layer, and a third conductive layer that are arranged on one side of the base and stacked. Insulating layers are arranged between adjacent conductive layers. For example, a pixel driving circuit arranged on the substrate 100 includes a transistor and a storage capacitor. The transistor includes a semiconductor, a gate, a source, and a drain. The storage capacitor includes a first plate and a second plate. As an example, the gate and the first plate may be located on the first conductive layer, the second plate may be located on the second conductive layer, and the source and the drain may be located on the third conductive layer. Optionally, the substrate 100 may further include a fourth conductive layer, the fourth conductive layer is located on a side of the third conductive layer facing away from the base, and the fourth conductive layer may be provided with a connection signal line, so that the first electrode 111 is connected to a driving circuit through the connection signal line. For example, the first electrode 111 is connected to a source or drain of a driving transistor through the connection signal line.

Optionally, the display panel 10 further includes a light-emitting layer, and the light-emitting layer includes a light-emitting unit 600 located in the isolation opening 410. Optionally, part of the light-emitting unit 600 may also be located in the first opening 310.

Optionally, a pixel defining layer 500 is provided on a side of the first electrode layer 110 facing away from the substrate 100, as shown in FIG. 2. The pixel defining layer 500 and the insulating protective layer 300 may be reused with each other, and the first opening 310 is reused as a pixel opening 520. Alternatively, in other embodiments, as shown in FIG. 3, the pixel defining layer 500 may be located between the light-transmitting conductive layer 200 and the first electrode layer 110, the pixel defining layer 500 includes a pixel defining portion 510 and a pixel opening 520 enclosed and formed by the pixel defining portion 510, and an orthographic projection of the pixel opening 520 on the substrate 100 at least partially overlaps with the orthographic projection of the first opening 310 on the substrate 100. The pixel opening 520 is configured to accommodate the light-emitting unit 600. Optionally, the orthographic projection of the pixel opening 520 on the substrate 100 is located within an orthographic projection of the first electrode 111 on the substrate 100, so that the first electrode 111 can drive the light-emitting unit 600 in the pixel opening 520 to emit light.

Optionally, the orthographic projection of the pixel opening 520 on the substrate 100 is located within the orthographic projection of the first opening 310 on the substrate 100, so that the insulating protective layer 300 may not cover the light-emitting unit 600 in the pixel opening 520 and may not affect a light-emitting effect of the light-emitting unit 600. Optionally, the orthographic projection of the pixel opening 520 on the substrate 100 is located within the orthographic projection of the isolation opening 410 on the substrate 100, so that the isolation structure 400 may not cover the light-emitting unit 600 in the pixel opening 520 and may not affect the light-emitting effect of the light-emitting unit 600. Optionally, the orthographic projection of the first opening 310 on the substrate 100 is located within the orthographic projection of the isolation opening 410 on the substrate 100, so that after the isolation opening 410 is manufactured, an insulating material layer is patterned through the isolation opening 410 to form the first opening 310.

Optionally, the display panel 10 further includes a second electrode layer 800, the second electrode layer 800 includes a second electrode 810 located on a side of each light-emitting unit 600 facing away from the substrate 100, and the second electrode 810 and the first electrode 111 interact with each other to drive the light-emitting unit 600 to emit light. One of the first electrode 111 and the second electrode 810 is an anode, and the other is a cathode. The present application is described based on an example in which the first electrode 111 is an anode the second electrode 810 is a cathode.

Optionally, the second electrode 810 and the isolation structure 400 are connected to each other, so that a plurality of second electrodes 810 can be interconnected into a surface electrode through the isolation structure 400.

The isolation structure 400 is arranged in a variety of manners. The isolation structure 400 has an integral structure and has a first bottom surface facing the substrate 100 and a first top surface facing away from the substrate 100. An orthographic projection of the first bottom surface on the substrate 100 is located within an orthographic projection of the first top surface on the substrate 100, that is, a size of the first bottom surface is smaller than that of the first top surface, so that the isolation structure 400 generally has a big-end-up structure, so as to form a recess on one side of the isolation structure 400. During subsequent manufacturing of the light-emitting units 600, a light-emitting material may be partitioned by the isolation structure 400 to form light-emitting units 600 that are independent of each other and located in the isolation opening 410.

Alternatively, as shown in FIG. 2 and FIG. 3, the isolation structure 400 includes a first sublayer 401 and a second sublayer 402 stacked in a direction away from the substrate 100. An orthographic projection of the first sublayer 401 on the substrate 100 is located within an orthographic projection of the second sublayer 402 on the substrate 100, that is, the second sublayer 402 protrudes from two sides of the first sublayer 401, and a size of the first sublayer 401 is smaller than that of the second sublayer 402, so that a recess can be formed under the second sublayer 402. During subsequent manufacturing of the light-emitting units 600, the light-emitting material may be partitioned by the isolation structure 400 to form light-emitting units 600 that are independent of each other and located in the isolation opening 410. Optionally, the isolation structure 400 may further include a third sublayer 403, the third sublayer 403 is located on a side of the first sublayer 401 facing the substrate 100, and the orthographic projection of the first sublayer 401 on the substrate 100 is located within an orthographic projection of the third sublayer 403 on the substrate 100, that is, the size of the first sublayer 401 is smaller than that of the third sublayer 403. During the manufacturing of the first sublayer 401, the third sublayer 403 may provide protection for a film layer located on a side of the isolation structure 400 facing the substrate 100.

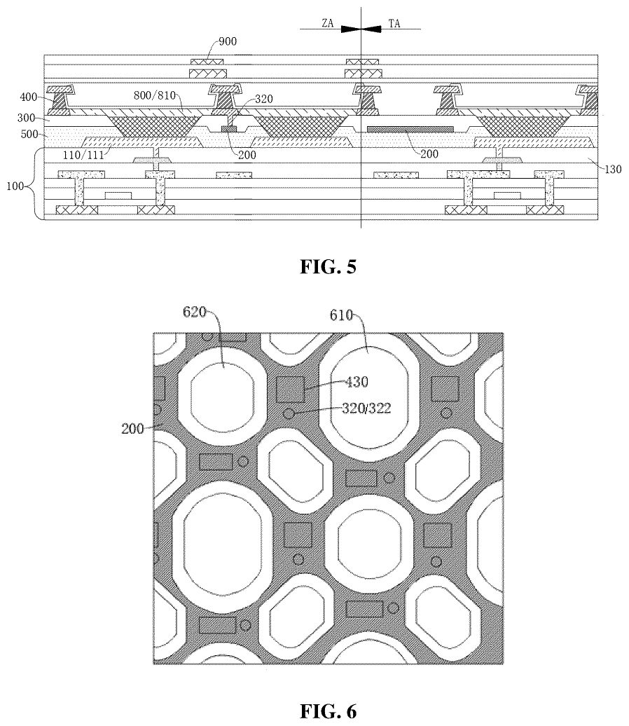

In other embodiments, as shown in FIG. 4 and FIG. 5, the display panel 10 includes a display region AA, the display region AA includes a main display region ZA and a light-transmitting display region TA, the light-transmitting conductive layer 200 and the insulating protective layer 300 are located in the light-transmitting display region TA, and the first light-transmitting opening 420 is located in the light-transmitting display region TA. The first light-transmitting opening 420 is provided in the light-transmitting display region TA to improve light transmittance of the light-transmitting display region TA.

In some embodiments, the display panel further includes an auxiliary conductive layer 240 located in the main display region ZA, and the auxiliary conductive layer 240 is electrically connected to the light-transmitting conductive layer 200, so that the light-transmitting conductive layer 200 may be connected to other components through the auxiliary conductive layer 240, and the light-transmitting conductive layer 200 may have a fixed potential.

Optionally, the auxiliary conductive layer 240 is arranged on a side of the isolation structure 400 close to the substrate 100. An orthographic projection of the auxiliary conductive layer on the substrate 100 is located within a range of an orthographic projection of the isolation structure 400 on the substrate 100, so as to facilitate the connection between the auxiliary conductive layer 240 and the isolation structure 400. Optionally, a shape of the auxiliary conductive layer 240 is the same as that of the isolation structure 400. That is, the auxiliary conductive layer 240 also has an auxiliary opening in the main display region ZA, and the auxiliary opening is located under the isolation opening 410. An area of the auxiliary opening is larger than that of the isolation opening 410, which facilitates the manufacturing of the light-emitting unit 600 and ensures a light-emitting area of the light-emitting unit 600.

In some embodiments, the auxiliary conductive layer 240 and the light-transmitting conductive layer 200 are connected to each other to realize the connection between the isolation structure 400 in the main display region ZA and the light-transmitting conductive layer 200, and have a same fixed potential. Further, the light-transmitting conductive layer 200 may extend from the light-transmitting display region TA to the main display region ZA, and the light-transmitting conductive layer 200 located in the main display region ZA forms the auxiliary conductive layer 240. That is, the light-transmitting conductive layer 200 and the auxiliary conductive layer 240 are arranged on a same layer and made of a same material. For example, the light-transmitting conductive layer 200 and the auxiliary conductive layer are made of a same material, so as to increase a contact area between the light-transmitting conductive layer 200 and the auxiliary conductive layer 240, improve strength of the connection thereof, and also simplify a manufacturing process of the display panel.

Optionally, the insulating protective layer 300 extends from the light-transmitting display region TA to the main display region ZA, covering the light-transmitting conductive layer 200 located in the main display region ZA. Optionally, the communication hole 320 includes a first communication hole 321 located in the main display region ZA and arranged through the insulating protective layer 300, and the isolation structure 400 is electrically connected to the auxiliary conductive layer 240 in the main display region ZA through the first communication hole 321 provided in the insulating protective layer 300. Therefore, the isolation structure 400 is electrically connected to the light-transmitting conductive layer 200 through the auxiliary conductive layer 240. In addition, both the main display region ZA and the light-transmitting display region TA are provided with the insulating protective layer 300, which can make structures of the light-transmitting display region TA and the main display region ZA tend to be consistent and improve display uniformity of the light-transmitting display region TA and the main display region ZA.

The first communication hole 321 is positioned in a variety of manners. Optionally, the first communication hole 321 may be distributed throughout the main display region ZA of the display panel 10.

In such optional embodiments, the first communication hole 321 is located in the main display region ZA rather than the light-transmitting display region TA, so that the first communication hole 321 may not occupy an area of the light-transmitting display region TA. More first light-transmitting openings 420 may be appropriately provided in the light-transmitting display region TA, or an area of the first light-transmitting opening 420 may be appropriately increased in the light-transmitting display region TA, so as to further improve the light transmittance of the light-transmitting display region TA. Moreover, at least part of the light-transmitting conductive layer 200 and the auxiliary conductive layer 240 in the main display region ZA are connected to each other, so that the light-transmitting conductive layer 200 can be connected to the isolation structure 400 through the first communication hole 321 located in the main display region ZA.

In some optional embodiments, the display panel 10 includes a light-emitting unit 600, the light-emitting unit 600 includes a first light-emitting unit 610 and a second light-emitting unit 620 located in different isolation openings 410 (i.e., different pixel openings 520), and the first communication hole 321 is located between the first light-emitting unit 610 and the second light-emitting unit 620. On the one hand, an influence of the first communication hole 321 on the light-emitting effect is ameliorated. On the other hand, a spacing between the first light-emitting unit 610 and the second light-emitting unit 620 is larger, which facilitates the arrangement of a larger-sized first communication hole 321, ensures a yield of connection between the isolation structure 400 and the light-transmitting conductive layer 200, and reduces signal transmission impedance.

In some optional embodiments, as shown in FIG. 6, the isolation structure 400 further encloses and forms a second light-transmitting opening 430 located in the main display region ZA, and a size of the second light-transmitting opening 430 may be the same as that of the first light-transmitting opening 420, so as to further improve the light transmittance of the entire display panel 10.

In some other embodiments, an area of an orthographic projection of the second light-transmitting opening 430 on the substrate 100 is smaller than an area of an orthographic projection of the first light-transmitting opening 420 on the substrate 100. That is, the size of the second light-transmitting opening 430 is smaller than that of the first light-transmitting opening 420, so as to ensure that the main display region ZA has a sufficient area for the communication hole 320.

Optionally, the second light-transmitting opening 430 is located between the first light-emitting unit 610 and the second light-emitting unit 620 adjacent to each other. For example, when the first light-emitting unit 610 and the second light-emitting unit 620 are distributed in an array along a first direction X and a second direction Y, the orthographic projection of the second light-transmitting opening 430 on the substrate 100 is located between orthographic projections of the first light-emitting unit 610 and the second light-emitting unit 620 adjacent to each other along the first direction X or the second direction Y on the substrate 100, so as to appropriately increase the size of the second light-transmitting opening 430.

Optionally, when the main display region ZA is provided with both the second light-transmitting opening 430 and the first communication hole 321, the first light-emitting unit 610 and the second light-emitting unit 620 are distributed in an array along the first direction X and the second direction Y, and the orthographic projection of at least one first communication hole 321 on the substrate 100 and the orthographic projection of the second light-transmitting opening 430 on the substrate 100 are arranged side by side along the first direction X, or the second direction Y, or the first direction X and the second direction Y.

For example, when the first communication hole 321 and the second light-transmitting opening 430 are correspondingly arranged between the first light-emitting unit 610 and the second light-emitting unit 620 arranged side by side along the first direction X, the first communication hole 321 and the second light-transmitting opening 430 are arranged side by side along the second direction Y, to reduce an overall size of the second light-transmitting opening 430 and the first communication hole 321 in the second direction Y and appropriately increase the sizes of the second light-transmitting opening 430 and the first communication hole 321 at the same time.

Alternatively, when the first communication hole 321 and the second light-transmitting opening 430 are correspondingly arranged between the first light-emitting unit 610 and the second light-emitting unit 620 arranged side by side along the second direction Y, the first communication hole 321 and the second light-transmitting opening 430 are arranged side by side along the first direction X, to reduce an overall size of the second light-transmitting opening 430 and the communication hole 320 in the first direction X and appropriately increase the sizes of the second light-transmitting opening 430 and the communication hole 320 at the same time.

Optionally, a projection of the insulating protective layer 300 located in the main display region ZA on the substrate 100 at least partially overlaps with the orthographic projection of the second light-transmitting opening 430 on the substrate 100, and the insulating protective layer 300 can be exposed through the second light-transmitting opening 430.

As described above, the light-emitting unit 600 includes a first light-emitting unit 610 and a second light-emitting unit 620 located in different isolation openings 410 (i.e., different pixel openings 520), and the first light-transmitting opening 420 is located between the first light-emitting unit 610 and the second light-emitting unit 620. The first light-transmitting opening 420 is correspondingly arranged between the first light-emitting unit 610 and the second light-emitting unit 620, which can ameliorate an influence of the first light-transmitting opening 420 on the light-emitting effect of the light-emitting unit 600. “The first light-transmitting opening 420 is located between the first light-emitting unit 610 and the second light-emitting unit 620” means that in a top view of the display panel 10, the first light-transmitting opening 420 is located between an orthographic projection of the first light-emitting unit 610 on the substrate 100 and an orthographic projection of the second light-emitting unit 620 on the substrate 100. For example, the first light-transmitting opening 420 has a first orthographic projection on the substrate 100, the first light-emitting unit 610 has a second orthographic projection on the substrate 100, and the second light-emitting unit 620 has a third orthographic projection on the substrate. The first orthographic projection is between the second orthographic projection and the third orthographic projection.

In some optional embodiments, the light-emitting layer comprises a plurality of light-emitting units 600, the plurality of light-emitting units 600 are arranged in an array, and at least one first light-transmitting opening 420 is located between two adjacent light-emitting units 600 in a same row or column, to ameliorate the influence of the first light-transmitting opening 420 on the light-emitting effect of the light-emitting unit 600. “At least one first light-transmitting opening 420 is located between two adjacent light-emitting units 600 in a same row or column” means that in the top view of the display panel 10, the first light-transmitting opening 420 is correspondingly located between two adjacent light-emitting units 600 in a same row or column. For example, when the first light-transmitting opening 420 has a first orthographic projection on the substrate 100, the light-emitting unit 600 has a second orthographic projection on the substrate 100, and the first orthographic projection is located between two adjacent second orthographic projections in a same row or column.

Optionally, the plurality of light-emitting units 600 are arranged in an array along the first direction X and the second direction Y, the light-transmitting opening 420 includes a first light-transmitting sub-opening and a second light-transmitting sub-opening, a length of the first light-transmitting sub-opening in the first direction X is greater than a length thereof in the second direction Y, and a length of the second light-transmitting sub-opening in the second direction Y is greater than a length thereof in the first direction X. Through the arrangement of the first light-transmitting sub-opening and the second light-transmitting sub-opening with different sizes, the first light-transmitting opening 420 can better match a gap between two adjacent light-emitting units 600, a distribution area of the first light-transmitting opening 420 can be increased, and the light transmittance of the display panel 10 can be improved.

Optionally, the first light-transmitting sub-opening is arranged between two light-emitting units 600 adjacent to each other along the second direction Y. An extension size of the gap between the two light-emitting units 600 adjacent to each other along the second direction Y is larger in the first direction X, so that the arrangement of the first light-transmitting sub-opening between the two light-emitting units 600 adjacent to each other along the second direction Y can appropriately increase a distribution area of the first light-transmitting sub-opening.

Optionally, the second light-transmitting sub-opening is arranged between two light-emitting units 600 adjacent to each other along the first direction X. An extension size of the gap between the two light-emitting units 600 adjacent to each other along the first direction X is larger in the second direction Y, so that the arrangement of the second light-transmitting sub-opening between the two light-emitting units 600 adjacent to each other along the first direction X can appropriately increase a distribution area of the second light-transmitting sub-opening.

Optionally, the plurality of light-emitting units 600 may further include a plurality of third light-emitting units 630, the plurality of first light-emitting units 610 and the plurality of second light-emitting units 620 are alternately arranged along the second direction Y to form a first pixel column 601, the plurality of third light-emitting units 630 are arranged along the second direction Y to form a second pixel column 602, and the first pixel column 601 and the second pixel column 602 are alternately arranged along the first direction X. The orthographic projection of the first light-transmitting opening 420 on the substrate 100 is located between the orthographic projections of the first light-emitting unit 610 and the second light-emitting unit 620 adjacent to each other along the first direction X, or the second direction Y, or the first direction X and the second direction Y on the substrate 100.

In such embodiments, the first pixel column 601 includes first light-emitting units 610 and second light-emitting units 620 alternately arranged along the second direction Y, the second pixel column 602 includes third light-emitting units 630 arranged along the second direction Y, and the first pixel column 601 and the second pixel column 602 are alternately arranged along the first direction X. A spacing between the first light-emitting unit 610 and the second light-emitting unit 620 may be larger than a spacing between the first light-emitting unit 610 and the third light-emitting unit 630 or between the second light-emitting unit 620 and the third light-emitting unit 630. The first light-transmitting opening 420 is correspondingly arranged between the first light-emitting unit 610 and the second light-emitting unit 620 adjacent to each other along the first direction X, or the second direction Y, or the first direction X and the second direction Y, that is, the first light-transmitting opening 420 is arranged in a larger gap, which can appropriately increase the distribution area of the first light-transmitting opening 420, thereby improving the light transmittance of the display panel 10.

Optionally, one of the first light-emitting unit 610 and the second light-emitting unit 620 is a blue light-emitting unit 600, and the other is a red light-emitting unit 600. The third light-emitting unit 630 is, for example, a green light-emitting unit 600. Therefore, the first light-emitting unit 610 and the second light-emitting unit 620 in the first pixel column 601 may be combined with the third light-emitting unit 630 in the second pixel column 602 to form a unit group for emitting white light.

Optionally, the third light-emitting unit 630 in the second pixel column 602 is correspondingly located between the first light-emitting unit 610 and the second light-emitting unit 620 adjacent to each other in the first pixel column 601. That is, the first pixel column 601 and the second pixel column 602 are misaligned in the first direction X, which can reduce the spacing between the first light-emitting unit 610 and the third light-emitting unit 630 and the spacing between the second light-emitting unit 620 and the third light-emitting unit 630, thereby improving the display effect.

Optionally, two second light-emitting units 620 and two first light-emitting units 610 are arranged on a peripheral side of the third light-emitting unit 630, and the two first light-emitting units 610 and the two second light-emitting units 620 are alternately arranged on the peripheral side of the third light-emitting unit 630. The spacing between the first light-emitting unit 610 and the third light-emitting unit 630 and the spacing between the second light-emitting unit 620 and the third light-emitting unit 630 can be further reduced, thereby improving the display effect.

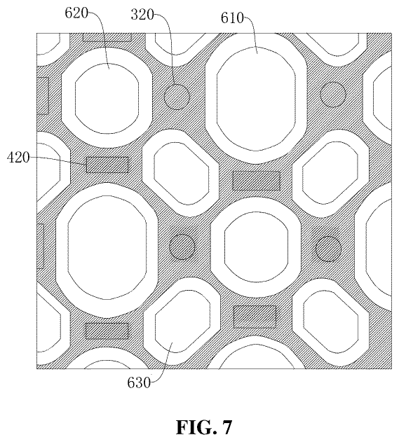

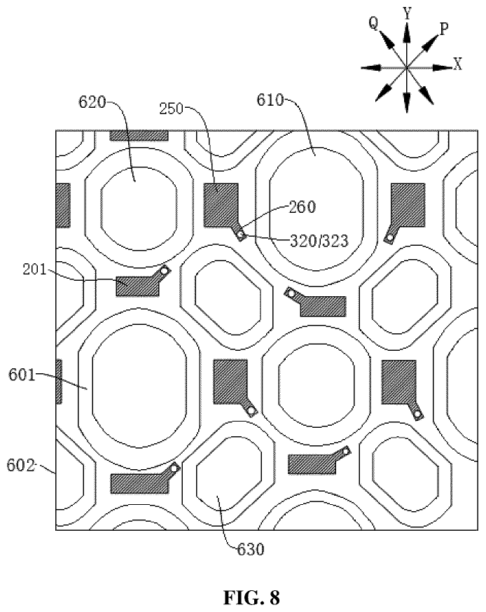

In some optional embodiments, as shown in FIG. 7, the communication hole 320 further includes a second communication hole 322, the light-transmitting conductive layer 200 is electrically connected to the isolation structure 400 through the second communication hole 322, and the first light-transmitting opening 420 and the second communication hole 322 are arranged at intervals on a peripheral side of the isolation opening 410. That is, the first light-transmitting opening 420 and the second communication hole 322 are correspondingly arranged on the peripheral side of the isolation opening 410, and the first light-transmitting opening 420 and the second communication hole 322 are arranged at intervals on the peripheral side of the isolation opening 410, which can increase a spacing between the first light-transmitting opening 420 and the second communication hole 322, increase an area of the second communication hole 322, and ensure a yield of connection between the light-transmitting conductive layer 200 and the isolation structure 400.

Optionally, an orthographic projection of the second communication hole 322 on the substrate 100 is located within the orthographic projection of the isolation structure 400 on the substrate 100, so that the light-transmitting conductive layer 200, or the auxiliary conductive layer 240, or the light-transmitting conductive layer 200 and the auxiliary conductive layer 240 may be electrically connected to the isolation structure 400 through the second communication hole 322.

Optionally, three first light-transmitting openings 420 and one second communication hole 322 may be arranged on the peripheral side of a same isolation opening 410, and the three first light-transmitting openings 420 and the one second communication hole 322 are distributed on different sides of the isolation opening 410. A larger number of first light-transmitting openings 420 can improve the light transmittance and ensure the yield of connection between the light-transmitting conductive layer 200 and the isolation structure 400.

Optionally, the second communication hole 322 may be located in the light-transmitting display region TA.

In some optional embodiments, the light-transmitting conductive layer 200 has a mesh structure and has a second opening 210, and an orthographic projection of the second opening 210 on the substrate 100 at least partially overlaps with an orthographic projection of the first opening 310 on the substrate 100. The mesh structure herein refers to an integrated film structure with a plurality of openings.

In such optional embodiments, the light-transmitting conductive layer 200 has a mesh structure, which can increase a distribution area of the light-transmitting conductive layer 200, facilitate an increase in the area of the first light-transmitting opening 420, and further improve the light transmittance of the display panel 10. The light-transmitting conductive layer 200 is provided with the second opening 210, and the orthographic projection of the second opening 210 on the substrate 100 at least partially overlaps with the orthographic projection of the first opening 310 on the substrate 100, so that the light-transmitting conductive layer 200 hardly affects light emission of the light-emitting unit 600.

Optionally, the orthographic projection of the first opening 310 on the substrate 100 is located within the orthographic projection of the second opening 210 on the substrate 100. That is, the second opening 210 has a larger size. On the one hand, the influence of the light-transmitting conductive layer 200 on the light-emitting effect of the light-emitting unit 600 can be better prevented. On the other hand, the first opening 310 has a smaller size, so that the insulating protective layer 300 can cover at least part of an inner wall surface of the light-transmitting conductive layer 200 facing the second opening 210, which can improve a protective effect of the insulating protective layer 300.

In other embodiments, the orthographic projection of the second opening 210 on the substrate 100 may alternatively be located within the orthographic projection of the first opening 310 on the substrate 100, that is, the first opening 310 has a larger size, which can ameliorate the influence of the insulating protective layer 300 on the light-emitting unit 600.

Optionally, as described above, when the display panel 10 further includes a pixel defining layer 500, the orthographic projection of the pixel opening 520 on the substrate 100 is located within the orthographic projection of the second opening 210 on the substrate 100, so that the second opening 210 provided in the light-transmitting conductive layer 200 has a larger size, and the light-transmitting conductive layer 200 hardly affects the light-emitting effect of the light-emitting unit 600.

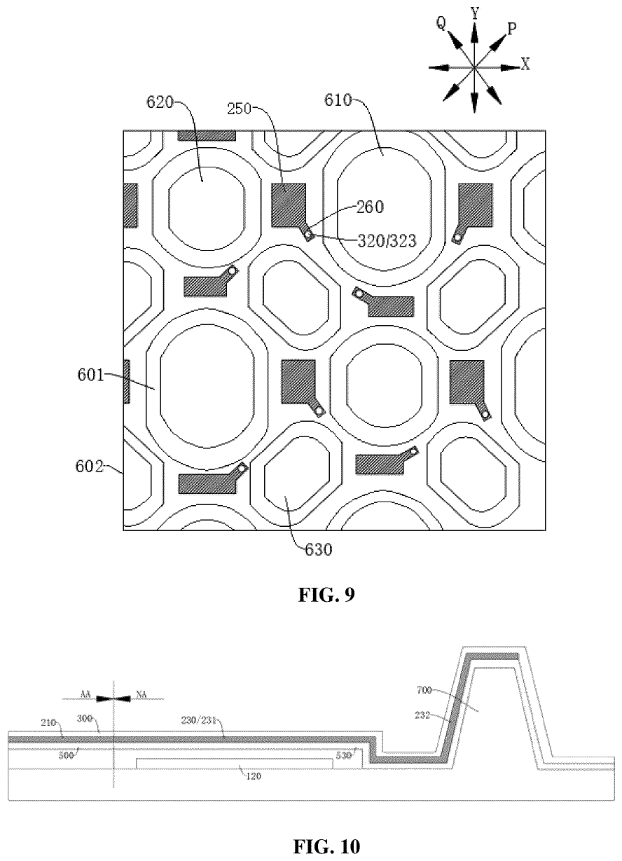

In some other optional embodiments, as shown in FIG. 8, the light-transmitting conductive layer 200 includes a plurality of light-transmitting conductive portions 201 arranged independently from each other. Optionally, the communication hole 320 further includes a plurality of third communication holes 323 arranged through the insulating protective layer 300, and the light-transmitting conductive portions 201 are electrically connected to the isolation structure 400 through the third communication holes 323.

In the display panel according to the embodiments of the present application, the light-transmitting conductive portion 201 is connected to the isolation structure 400 above through the third communication hole 323, so that the light-transmitting conductive portion 201 and the isolation structure 400 can have a same fixed potential. During subsequent manufacturing of the touch electrode 900, the problem of parasitic capacitance produced between the touch electrode 900 and the wires in the substrate 100 through the first light-transmitting opening 420 can be alleviated, and the process performance of the display panel 10 can be improved.

Optionally, an orthographic projection of the light-transmitting conductive portion 201 on the substrate 100 at least partially overlaps with the orthographic projection of the first light-transmitting opening 420 on the substrate 100, so that the light-transmitting conductive portion 201 can block at least part of signal transmission of the first light-transmitting opening 420, which alleviates the problem of parasitic capacitance produced between the touch electrode 900 and the wires in the substrate 100 through the first light-transmitting opening 420, prevents transmission noise of the touch electrode 900, and improves the process performance of the display panel 10.

In some optional embodiments, the light-transmitting conductive portion 201 includes a shielding portion 250 and a connecting portion 260, an orthographic projection of the shielding portion 250 on the substrate 100 at least partially overlaps with the orthographic projection of the first light-transmitting opening 420 on the substrate 100, and the isolation structure 400 and the light-transmitting conductive portion 201 are via connected through the third communication hole 323.

In such embodiments, the light-transmitting conductive portion 201 is divided into the shielding portion 250 and the connecting portion 260, and the connecting portion 260 and the isolation structure 400 are connected to each other, so that the light-transmitting conductive portion 201 may have a fixed potential. The orthographic projection of the shielding portion 250 on the substrate 100 at least partially overlaps with the orthographic projection of the first light-transmitting opening 420 on the substrate 100, that is, the shielding portion 250 of the light-transmitting conductive portion 201 is arranged correspondingly to the light-transmitting opening 420, so that during the subsequent manufacturing of the touch electrode 900, the problem of parasitic capacitance produced between the touch electrode 900 and the wires in the substrate 100 through the first light-transmitting opening 420 can be alleviated, and the process performance of the display panel 10 can be improved.

Optionally, an area of the orthographic projection of the shielding portion 250 on the substrate 100 is greater than an area of an orthographic projection of the connecting portion 260 on the substrate 100. The shielding portion 250 has a larger area, so that the light-transmitting conductive portion 201 can block more signals passing through the first light-transmitting opening 420, which better alleviates the problem of parasitic capacitance produced between the touch electrode 900 and the wires in the substrate 100 through the first light-transmitting opening 420.

Optionally, the orthographic projection of the first light-transmitting opening 420 on the substrate 100 is located within a range of the orthographic projection of the shielding portion 250 on the substrate 100. Therefore, the shielding portion 250 can completely block the first light-transmitting opening 420, which better alleviates the problem of parasitic capacitance produced between the touch electrode 900 and the wires in the substrate 100 through the first light-transmitting opening 420.

The light-transmitting conductive portion 201 is positioned in a variety of manners. Optionally, as shown in FIG. 8, the light-emitting unit 600 further includes a first light-emitting unit 610 and a second light-emitting unit 620 arranged at intervals, and the shielding portion 250 is located between the first light-emitting unit 610 and the second light-emitting unit 620.

Lengths of the first light-emitting unit 610 and the second light-emitting unit 620 in the first direction X are less than lengths thereof in the second direction, so that a gap between the first light-emitting unit 610 and the second light-emitting unit 620 adjacent to each other in the first direction X is larger than a gap in the second direction Y.

In such optional embodiments, the shielding portion 250 is correspondingly located between the first light-emitting unit 610 and the second light-emitting unit 620 adjacent to each other, which can ameliorate a short-circuit connection between the shielding portion 250 and the first electrode 111 for driving the first light-emitting unit 610 and the second light-emitting unit 620 and can also ameliorate an influence of the shielding portion 250 on light-emitting effects of the first light-emitting unit 610 and the second light-emitting unit 620.

“The shielding portion 250 is located between the first light-emitting unit 610 and the second light-emitting unit 620” means that in the top view of the display panel, the shielding portion 250 is correspondingly located between the first light-emitting unit 610 and the second light-emitting unit 620. For example, when the shielding portion 250 has a first orthographic projection on the substrate 100, the first light-emitting unit 610 has a second orthographic projection on the substrate 100, and the second light-emitting unit 620 has a third orthographic projection on the substrate 100. On the substrate 100, the first orthographic projection is between the second orthographic projection and the third orthographic projection.

Optionally, as described above, the light-emitting unit 600 further includes a third light-emitting unit 630, a plurality of first light-emitting units 610 and a plurality of second light-emitting units 620 are alternately arranged along the second direction Y to form a first pixel column 601, a plurality of third light-emitting units 630 are arranged along the second direction Y to form a second pixel column 602, and the first pixel column 601 and the second pixel column 602 are alternately arranged along the first direction X.

Optionally, in the above arrangement manner, a spacing between the first light-emitting unit 610 and the second light-emitting unit 620 may be larger than a spacing between the first light-emitting unit 610 and the third light-emitting unit 630 or between the second light-emitting unit 620 and the third light-emitting unit 630, and the shielding portion 250 is correspondingly arranged between the first light-emitting unit 610 and the second light-emitting unit 620, that is, the first light-transmitting opening 420 is correspondingly arranged between the first light-emitting unit 610 and the second light-emitting unit 620, which can appropriately increase an area of the shielding portion 250 and appropriately increase an area of the first light-transmitting opening 420, thereby improving the light transmittance of the display panel 10.

Optionally, the orthographic projection of the shielding portion 250 on the substrate 100 is located between orthographic projections of the first light-emitting unit 610 and the second light-emitting unit 620 adjacent to each other along the first direction X, or the second direction Y, or the first direction X and the second direction Y on the substrate 100. Spacings between the first light-emitting unit 610 and the second light-emitting unit 620 adjacent to each other along the first direction X and between the first light-emitting unit 610 and the second light-emitting unit 620 adjacent to each other along the second direction Y are both larger, and the shielding portion 250 is such positioned that it is easy to appropriately increase a distribution area of the shielding portion 250.

The third communication hole 323 is positioned in a variety of manners. For example, the third communication hole 323 and the shielding portion 250 may be arranged side by side along the first direction X or the second direction Y. That is, the connecting portion 260 and the shielding portion 250 are arranged side by side along the first direction X or the second direction Y.

Alternatively, in other embodiments, an orthographic projection of the third communication hole 323 on the substrate 100 is located on a side of the first light-emitting unit 610 or the second light-emitting unit 620 in a third direction. The third direction intersects the first direction X and the second direction Y in a same plane. The third direction may be a direction P or Q in FIG. 8. For example, there is a first reference connection line between centers of the orthographic projection of the third communication hole 323 on the substrate 100 and the first light-emitting unit 610 or the second light-emitting unit 620 closest thereto. The first reference connection line extends along the third direction. The first reference connection line intersects the first direction X and the second direction Y in a same plane. For example, when the third communication hole 323 is closer to a certain first light-emitting unit 610, there is a first reference connection line between centers of the orthographic projection of the third communication hole 323 on the substrate 100 and the first light-emitting unit 610. The first reference connection line is a virtual reference line created to explain the position of the communication hole 320 more clearly, and is only used to define a relative positional relationship between the communication hole 320 and the light-emitting unit 600, which does not constitute a limitation on the structure of the display panel in the embodiments of the present application.

In such embodiments, the shielding portion 250 is correspondingly located between two light-emitting units 600 adjacent to each other along the first direction X or the second direction Y, and the third communication hole 323 is correspondingly located on a side of the first light-emitting unit 610 or the second light-emitting unit 620 in the third direction, so that there is an angle position setting between the third communication hole 323 and the closest light-emitting unit 600. The third communication hole 323 and the shielding portion 250 are distributed at intervals around the first light-emitting unit 610 or the second light-emitting unit 620, so as to ameliorate interference from the relative position between the communication hole 320 and the shielding portion 250, which facilitates an appropriate increase in the size of the shielding portion 250, thereby facilitating an appropriate increase in the size of the first light-transmitting opening 420. In addition, a sufficient space can also be left for the arrangement of the third communication hole 323.

Optionally, an angle between the first reference connection line and the first direction X or the second direction Y ranges from 30 degrees to 60 degrees, to prevent an influence on the arrangement of the communication hole 320 due to an excessively short distance between the communication hole 320 and the shielding portion 250 and an excessively short distance between the first light-transmitting opening 420 and the communication hole 320 caused by an excessively small or large angle.

Optionally, the angle between the first reference connection line and the first direction X or the second direction Y is 45 degrees, so that the shielding portion 250 and the third communication hole 323 can be relatively evenly distributed in a plane.

In some optional embodiments, there is a second reference connection line between a center of the orthographic projection of the third communication hole 323 on the substrate 100 and a center of the orthographic projection of the shielding portion 250 on the substrate 100. The second reference connection line intersects the first direction X and the second direction Y in a same plane. That is, the third communication hole 323 is located on a side of the shielding portion 250 in the third direction, so that the third communication hole 323 and the shielding portion 250 can be located on a peripheral side of the first light-emitting unit 610 or the second light-emitting unit 620, which facilitates an appropriate increase in the distribution area of the communication hole 320 and the shielding portion.

The second reference connection line is arranged in a same manner as the first reference connection line. For example, an angle between the second reference connection line and the first direction X or the second direction Y ranges from 30 degrees to 60 degrees. Optionally, the angle between the second reference connection line and the first direction X or the second direction Y is 45 degrees.

Optionally, the orthographic projection of the isolation structure 400 on the substrate 100 covers an orthographic projection of the communication hole 320 on the substrate 100, which facilitates the isolation structure 400 to be via connected to the light-transmitting conductive portion 201 through the communication hole 320.

Optionally, the third communication hole 323 may be located between the first light-emitting unit 610 and the third light-emitting unit 630, and the third communication hole 323 may alternatively be located between the second light-emitting unit 620 and the third light-emitting unit 630. The third communication hole 323 is correspondingly located between two light-emitting units 600 with a smaller spacing, so that the third communication hole 323 may not occupy an excessively large space, which facilitates the arrangement of the shielding portion 250 and the first light-transmitting opening 420.

In some other embodiments, the orthographic projection of the third communication hole 323 on the substrate 100 may alternatively be located between the orthographic projection of the first light-emitting unit 610 on the substrate 100 and the orthographic projection of the second light-emitting unit 620 on the substrate 100. The third communication hole 323 is correspondingly arranged between two light-emitting units 600 with a larger spacing, which facilitates an appropriate increase in the size of the third communication hole 323.

In the above embodiments, the light-transmitting conductive portions 201 are arranged independently from each other, that is, each first light-transmitting opening 420 is correspondingly provided with an independently arranged light-transmitting conductive portion 201, which can minimize the distribution area of the light-transmitting conductive portion 201, thereby ameliorating interference between arrangement of the light-transmitting conductive portion 201 and other signal lines, also facilitating an appropriate increase in the size of the light-emitting unit 600, and improving the display effect.

When the light-transmitting conductive portions 201 are arranged independently from each other, the connecting portion 260 of each light-transmitting conductive portion 201 is located on a side of the shielding portion 250 in the third direction. There is a third reference connection line between the connecting portion 260 and the shielding portion 250. The third reference connection line intersects the first direction X and the second direction Y in a same plane. That is, each shielding portion 250 has a connecting portion 260 protruding along the third direction. The size of the connecting portion 260 may be smaller, as long as the size can ensure that the connecting portion 260 and the isolation structure 400 can be electrically connected to each other through the third communication hole 323.

The third reference connection line may be arranged in a same manner as the first reference connection line. For example, an angle between the third reference connection line and the first direction X or the second direction Y ranges from 30 degrees to 60 degrees. Optionally, the angle between the third reference connection line and the first direction X or the second direction Y is 45 degrees.

Optionally, an area of the orthographic projection of the shielding portion 250 on the substrate 100 is greater than an area of an orthographic projection of the connecting portion 260 on the substrate 100. The shielding portion 250 has a larger size, and the first light-transmitting opening 420 may have a larger size, thereby improving the light transmittance of the display panel 10. The connecting portion 260 has a smaller size, which can reduce an overall distribution size of the light-transmitting conductive portion 201, thereby ameliorating interference between arrangement of the light-transmitting conductive portion 201 and other signal lines, also facilitating an appropriate increase in the size of the light-emitting unit 600, and improving the display effect.

In some other optional embodiments, as shown in FIG. 9, at least two adjacent light-transmitting conductive portions 201 may be connected to each other. For example, at least two adjacent light-transmitting conductive portions 201 located on a peripheral side of the light-emitting unit 600 may be connected to each other, to simplify a patterning process when the light-transmitting conductive portions 201 are manufactured, and improve manufacturing efficiency.

Optionally, the connecting portions 260 of two adjacent light-transmitting conductive portions 201 are connected to each other. That is, the shielding portions 250 of the two adjacent light-transmitting conductive portions 201 are connected to each other through the connecting portion 260. The size of the connecting portion 260 is generally smaller than that of the shielding portion 250. Connecting the adjacent shielding portions 250 through the connecting portion 260 can reduce an overall size of the light-transmitting conductive portion 201 and facilitate an appropriate increase in the size of the light-emitting unit 600, thereby improving the display effect.

Optionally, the two light-transmitting conductive portions 201 connected to each other through the connecting portion 260 share a same communication hole 320 and are connected to the isolation structure 400. That is, the two light-transmitting conductive portions 201 connected to each other are connected to the isolation structure 400 through the same communication hole 320, which can appropriately reduce a number of the third communication hole 323 and simplify a manufacturing process of the insulating protective layer 300.

Optionally, two light-transmitting conductive portions 201 located on a peripheral side of a same first light-emitting unit 610 or a same second light-emitting unit 620 are connected to each other. For example, the light-transmitting conductive portion 201 located on a side of the first light-emitting unit 610 in the first direction X and the light-transmitting conductive portion 201 located on a side of the first light-emitting unit 610 in the second direction Y are connected to each other, so that a distance between the light-transmitting conductive portions 201 connected to each other is smaller, which can simplify a manufacturing process and a yield of connection between the light-transmitting conductive portions 201.

Optionally, the display panel 10 further includes a non-display region NA adjacent to the display region AA. A trace of the touch electrode 900 extends to the non-display region NA to be connected to a touch driving circuit. In the non-display region NA, parasitic capacitance may also be produced between the trace of the touch electrode 900 and the wires in the substrate 100.

In some optional embodiments, as shown in FIG. 2 to FIG. 10, the light-transmitting conductive layer 200 includes a first conductive portion 220 located in the display region AA and a second conductive portion 230 located in the non-display region NA, and the first conductive portion 220 and the isolation structure 400 are connected to each other.

In such optional embodiments, the light-transmitting conductive layer 200 is divided into the first conductive portion 220 located in the display region AA and the second conductive portion 230 located in the non-display region NA, and the first conductive portion 220 and the isolation structure 400 are connected to each other, so that the first conductive portion 220 can have a fixed potential to alleviate the problem of parasitic capacitance between the touch electrode 900 and the wires in the substrate 100 in the display region AA, and the second conductive portion 230 in the non-display region NA can alleviate the problem of parasitic capacitance produced between the trace of the touch electrode 900 and the wires in the substrate 100 in the non-display region NA, so as to further improve the process performance of the display panel 10.

Optionally, the first conductive portion 220 and the second conductive portion 230 may be connected to each other, so that the second conductive portion 230 can be connected to the isolation structure 400 through the first conductive portion 220. The second conductive portion 230 can also have a fixed potential, further alleviating the problem of parasitic capacitance produced between the trace of the touch electrode 900 and the wires in the substrate 100 in the non-display region NA.

Optionally, the substrate 100 is provided with a signal line 120 located in the non-display region NA, and an orthographic projection of the signal line 120 on the substrate 100 at least partially overlaps with an orthographic projection of the second conductive portion 230 on the substrate 100, so that the second conductive portion 230 can alleviate the problem of parasitic capacitance produced between the trace of the touch electrode 900 and the signal line 120. The signal line 120 may be a fan-out line or the like.

Optionally, the insulating protective layer 300 extends from the display region AA to the non-display region NA, and the insulating protective layer 300 covers the light-transmitting conductive layer 200 in the display region AA and the non-display region NA, to provide more complete protection for the light-transmitting conductive layer 200.

Optionally, the display panel 10 further includes a dam 700 located in the non-display region NA and arranged on one side of the substrate 100, and at least part of the second conductive portion 230 is arranged on a side of the dam 700 facing the display region AA. That is, the second conductive portion 230 extends into a region defined by the dam 700 to facilitate the manufacturing of the second conductive portion 230. In addition, the dam 700, that is, a side of the dam 700 facing away from the display region AA, is generally provided with a first inorganic encapsulation layer and a second inorganic encapsulation layer in contact with each other. The second conductive portion 230 is limited in the dam 700, which can ameliorate an influence of an outer region of the dam 700 on an encapsulation effect of the second conductive portion 230 and further improve reliability of the first conductive portion 220.

Optionally, the second conductive portion 230 includes a first segment 231 located on the side of the dam 700 facing the display region AA and a second segment 232 covering at least part of a surface of the dam 700, and the second segment 232 and the first segment 231 are connected to each other. In such optional embodiments, part of the second conductive portion 230 extends to the dam 700 to form the second segment 232, which can increase a distribution area of the second conductive portion 230 and better reduce transmission impedance of the second conductive portion 230.

The second segment 232 is arranged in a variety of manners. The second segment 232 may cover a side surface on the side of the dam 700 facing the display region AA, or the second segment 232 covers the side surface on the side of the dam 700 facing the display region AA and a top surface of the dam 700 facing away from the substrate 100.

Optionally, as described above, when the display panel includes a pixel defining layer 500, the pixel defining layer 500 includes a pad portion 530, and the pad portion 530 is located in the non-display region NA. That is, the pixel defining layer 500 includes a pixel defining portion 510 located in the display region AA and the pad portion 530 located in the non-display region NA. The pad portion 530 is located on a side of the second conductive portion 230 facing the substrate 100, to improve flatness of a surface of a film structure on the side of the second conductive portion 230 facing the substrate 100.

Optionally, the pad portion 530 further covers at least part of the dam 700, to increase a height of the dam 700, ensure integrity of a film layer between the display region AA and the non-display region NA, and improve an encapsulation effect of a structure of the display region AA.

Optionally, the non-display region NA may be a bezel region arranged around the display region AA.

Alternatively, in some other optional embodiments, the non-display region NA includes a hole region, and the dam 700 and the display region AA are both arranged around the hole region. The second conductive portion 230 located in the non-display region NA may be arranged around the hole region, thereby ameliorating an influence of parasitic capacitance between the touch electrode on a peripheral side of the hole region and a lower film layer.

Optionally, the display panel may include a touch layer located on a side of the isolation structure 400 away from the substrate 100. The touch layer may include the touch electrode 900 to implement a touch function of the display panel.

A material of the light-transmitting conductive layer 200 is provided in a variety of manners. A material of the conductive functional layer includes, for example, at least one of indium tin oxide and indium zinc oxide to further improve the light transmittance of the display panel 10. A material of the insulating protective layer also includes a light-transmitting material.

In this case, when the orthographic projection of the first light-transmitting opening 420 on the substrate 100 and the orthographic projection of the communication hole 320 on the substrate 100 are arranged at intervals on a peripheral side of the orthographic projection of the isolation opening 410 on the substrate 100, both the first light-transmitting opening 420 and the communication hole 320 may be located in the light-transmitting display region TA.

Optionally, a material of the pixel defining layer 500 may be an inorganic material, so that a thickness of the pixel defining layer 500 can be appropriately reduced and an overall thickness of the display panel 10 can be reduced. An inorganic material is selected as the material of the pixel defining layer 500, making it easier to control a shape of the second opening 210 and an inclination angle of a wall surface of the pixel defining portion 510 facing the second opening 210.

Optionally, as above, when the isolation structure 400 includes the first sublayer 401 and the second sublayer 402, the first sublayer 401 is connected to the light-transmitting conductive layer 200 through the communication hole 320. The first sublayer 401 is closer to the light-transmitting conductive layer 200 than the second sublayer 402, and the first sublayer 401 is more easily connected to the light-transmitting conductive layer 200 through the connecting hole 320.

The first sublayer 401 and the light-transmitting conductive layer 200 may be directly connected to each other. Alternatively, in some other embodiments, the isolation structure 400 further includes a third sublayer 403 located on a side of the first sublayer 401 facing the substrate 100, an orthographic projection of the first sublayer 401 on the substrate 100 is located within an orthographic projection of the third sublayer 403 on the substrate 100, and the third sublayer 403 is connected to the light-transmitting conductive layer 200 through the communication holes 320, so that the first sublayer 401 is connected to the light-transmitting conductive layer 200 through the third sublayer 403.

In addition, through the arrangement of the third sublayer 403, when the first sublayer 401 is side-etched so that the orthographic projection of the first sublayer 401 on the substrate 100 is located within the orthographic projection of the second sublayer 402 on the substrate 100, the material located under the third sublayer 403 can be protected to prevent damages to a layer structure under the third sublayer 403.

Optionally, the display panel 10 further includes an encapsulation layer, the encapsulation layer may include a first encapsulation layer, the first encapsulation layer includes an encapsulation portion located on a side of each second electrode 810 facing away from the substrate 100, and each light-emitting unit 600 can be provided with sealing protection through the encapsulation portion. A material of the first encapsulation layer may include an inorganic material.

Optionally, the encapsulation layer further includes a second encapsulation layer located on a side of the first encapsulation layer facing away from the substrate 100, the second encapsulation layer is located on a side of the structure of the dam 700 facing the display region AA, and the structure of the dam 700 can ameliorate overflowing of a material of the second encapsulation layer to a side of the structure of the dam 700 away from the display region AA. The material of the second encapsulation layer may include an organic material.

Optionally, the second encapsulation layer is in contact with at least part of a protective portion. For example, the first encapsulation layer does not encapsulate the first light-transmitting opening 420, and the first encapsulation layer only encapsulates a region where the isolation opening 410 is located, so that the second encapsulation layer can be in direct contact with the protective portion within the first light-transmitting opening 420.

Optionally, the encapsulation layer further includes a third encapsulation layer located on a side of the second encapsulation layer facing away from the substrate 100, and a material of the third encapsulation layer may be the same as that of the first encapsulation layer. For example, the material of the third encapsulation layer is an inorganic material.

In the first aspect of the present application, a display panel is further provided. The display panel includes: a substrate 100; a light-transmitting conductive layer 200 arranged on one side of the substrate 100, the light-transmitting conductive layer 200 having a mesh structure and having a second opening 210; an isolation structure 400 arranged on a side of the light-transmitting conductive layer 200 facing away from the substrate 100, the isolation structure 400 enclosing and forming an isolation opening 410 and a first light-transmitting opening 420, and an orthographic projection of the isolation opening 410 on the substrate 100 being located within an orthographic projection of the second opening 210 on the substrate 100; and a light-emitting layer including a light-emitting unit 600 located in the isolation opening 410. An orthographic projection of the first light-transmitting opening 420 on the substrate 100 is located within an orthographic projection of the light-transmitting conductive layer 200 on the substrate 100, and the isolation structure 400 is electrically connected to the light-transmitting conductive layer 200.

In the embodiments of the present application, due to the existence of the first light-transmitting opening 420, a touch electrode 900 subsequently manufactured may produce an electric field effect and parasitic capacitance between the first light-transmitting opening 420 and wires in the substrate 100. The corresponding arrangement of the light-transmitting conductive layer 200 and the first light-transmitting opening 420 can ameliorate the above parasitic capacitance. The light-transmitting conductive layer 200 is electrically connected to the isolation structure 400, so that the light-transmitting conductive layer 200 can have a fixed potential, thereby better alleviating the problem of parasitic capacitance. Therefore, according to the embodiments of the present application, through the arrangement of the light-transmitting conductive layer 200 and the mutual electrical connection between the light-transmitting conductive layer 200 and the isolation structure 400, the parasitic capacitance in the display panel 10 can be ameliorated, signal transmission of the touch electrode 900 can be improved, and process performance of the display panel 10 can be improved.

Optionally, the above display panel may further include an insulating protective layer 300. The insulating protective layer 300 is arranged in a manner as described above, which is not described in detail herein.

In the first aspect of the present application, a display panel is further provided. The display panel includes: a substrate 100; a light-transmitting conductive layer 200 arranged on one side of the substrate 100, the light-transmitting conductive layer 200 including a plurality of light-transmitting conductive portions 201 arranged at intervals; an isolation structure 400 arranged on a side of the light-transmitting conductive layer 200 facing away from the substrate 100, the isolation structure 400 enclosing and forming an isolation opening 410 and a first light-transmitting opening 420; and a light-emitting layer including a light-emitting unit 600 located in the isolation opening 410. An orthographic projection of the first light-transmitting opening 420 on the substrate 100 is located within an orthographic projection of the light-transmitting conductive layer 200 on the substrate 100, and the isolation structure 400 is electrically connected to the light-transmitting conductive layer 200.

Optionally, the above display panel may further include an insulating protective layer 300. The insulating protective layer 300 is arranged in a manner as described above, which is not described in detail herein. In a second aspect of the present application, an embodiment further provides a display apparatus, including the display panel 10 according to any one of the embodiments in the first aspect. Since the display apparatus according to the embodiment in the second aspect of the present application includes the display panel 10 in any one of the embodiments in the first aspect, the display apparatus according to the embodiment in the second aspect of the present application has the beneficial effects of the display panel 10 in any one of the embodiments in the first aspect. Details are not described herein again in this embodiment.

The display apparatus in the embodiments of the present application includes, but is not limited to, a mobile phone, a personal digital assistant (PDA), a tablet computer, an e-book, a television, an access control, a smart fixed phone, a console, and other devices with a display function.

In a third aspect of the present application, an embodiment further provides a manufacturing method for a display panel 10. The display panel 10 may be the display panel 10 according to any one of the embodiments in the first aspect. As shown in FIG. 1 to FIG. 11, the manufacturing method for a display panel 10 may include the following steps.

In step S01, a conductive functional material layer is arranged on a substrate 100, and the conductive functional material layer is patterned to obtain a light-transmitting conductive layer 200.

In step S02, an insulating material layer is arranged on one side of the light-transmitting conductive layer 200, the insulating material layer is patterned to obtain an insulating protective layer 300, a first opening 310 and a communication hole 320 are arranged through the insulating protective layer 300, and the light-transmitting conductive layer 200 is exposed through the communication hole 320.

In step S03, an isolation structure 400 is manufactured on a side of the insulating protective layer 300 facing away from the substrate 100, the isolation structure 400 encloses and forms an isolation opening 410 and a first light-transmitting opening 420, and the isolation structure 400 is connected to the light-transmitting conductive layer 200 through the communication hole 320.

Optionally, the insulating material layer may be patterned to form a first opening 310 before or after step S03. When the display panel 10 includes a pixel defining layer 500, the pixel defining layer 500 is patterned to form a pixel opening 520 after the first opening 310 is formed.

In the display panel 10 manufactured with the method according to the embodiments of the present application, the display panel 10 includes a substrate 100 and a light-transmitting conductive layer 200, an insulating protective layer 300, and an isolation structure 400 that are arranged on the substrate 100, and the insulating protective layer 300 arranged on a side of the light-transmitting conductive layer 200 facing away from the substrate 100 can protect the light-transmitting conductive layer 200. The isolation structure 400 encloses and forms an isolation opening 410 and a first light-transmitting opening 420. The isolation opening 410 is configured to accommodate a light-emitting unit 600. The first light-transmitting opening 420 is configured to improve light transmittance of the display panel 10. Due to the existence of the first light-transmitting opening 420, a touch electrode 900 subsequently manufactured may produce an electric field effect and parasitic capacitance between the first light-transmitting opening 420 and wires in the substrate 100. The corresponding arrangement of the light-transmitting conductive layer 200 and the first light-transmitting opening 420 can ameliorate the above parasitic capacitance. The light-transmitting conductive layer 200 is electrically connected to the isolation structure 400 through the communication hole 320, so that the light-transmitting conductive layer 200 can have a fixed potential, thereby better alleviating the problem of parasitic capacitance. Therefore, according to the embodiments of the present application, through the arrangement of the light-transmitting conductive layer 200 and the mutual connection between the light-transmitting conductive layer 200 and the isolation structure 400, the parasitic capacitance in the display panel 10 can be ameliorated, signal transmission of the touch electrode 900 can be improved, and process performance of the display panel 10 can be improved.

Although the present application has been described with reference to the preferred embodiments, various modifications may be made thereto and components may be replaced with equivalents without departing from the scope of the present application. In particular, the technical features mentioned in various embodiments can be combined in any manner provided that there is no structural conflict. The present application is not limited to the specific embodiments disclosed herein, but includes all technical solutions falling into the protection scope of the claims.

What is claimed is:

1. A display panel, comprising:
a substrate;
a light-transmitting conductive layer arranged on one side of the substrate;
an insulating protective layer arranged on a side of the light-transmitting conductive layer facing away from the substrate;
an isolation structure arranged on a side of the insulating protective layer facing away from the substrate, the isolation structure enclosing and forming an isolation opening and a first light-transmitting opening; and
a light-emitting layer comprising a light-emitting unit located in the isolation opening;
wherein an orthographic projection of the first light-transmitting opening on the substrate is located within an orthographic projection of the light-transmitting conductive layer on the substrate, and the orthographic projection of the first light-transmitting opening on the substrate is located within a range of an orthographic projection of the insulating protective layer on the substrate.

2. The display panel of claim 1, wherein
the display panel comprises a display region, the display region comprising a main display region and a light-transmitting display region;
the light-transmitting conductive layer and the insulating protective layer are located in the light-transmitting display region; and
the first light-transmitting opening is located in the light-transmitting display region.

3. The display panel of claim 2, wherein the display panel further comprises an auxiliary conductive layer located in the main display region, the auxiliary conductive layer being electrically connected to the light-transmitting conductive layer;
the auxiliary conductive layer is arranged on a side of the isolation structure close to the substrate, and an orthographic projection of at least part of the auxiliary conductive layer on the substrate is located within a range of an orthographic projection of the isolation structure on the substrate; and
the insulating protective layer extends to the main display region and covers the auxiliary conductive layer, a first communication hole is further arranged through the insulating protective layer in the main display region, and the isolation structure and the light-transmitting conductive layer are via connected through the first communication hole; and the light-transmitting conductive layer and the auxiliary conductive layer are arranged on a same layer and made of a same material.

4. The display panel of claim 3, wherein the light-emitting unit comprises a first light-emitting unit and a second light-emitting unit, and the first communication hole is located between the first light-emitting unit and the second light-emitting unit.

5. The display panel of claim 4, wherein the isolation structure further encloses and forms a second light-transmitting opening located in the main display region, and an area of an orthographic projection of the second light-transmitting opening on the substrate is smaller than an area of an orthographic projection of the first light-transmitting opening on the substrate;
the second light-transmitting opening is located between the first light-emitting unit and the second light-emitting unit adjacent to each other;
the first light-emitting unit and the second light-emitting unit are distributed in an array along a first direction and a second direction, and an orthographic projection of at least one first communication hole on the substrate and an orthographic projection of the second light-transmitting opening on the substrate are arranged side by side along the first direction, or the second direction, or the first direction and the second direction; and
the orthographic projection of the insulating protective layer located in the main display region on the substrate at least partially overlaps with the orthographic projection of the second light-transmitting opening on the substrate.

6. The display panel of claim 1, wherein the light-emitting unit comprises a first light-emitting unit and a second light-emitting unit, and the first light-transmitting opening is located between the first light-emitting unit and the second light-emitting unit.

7. The display panel of claim 1, wherein the light-emitting layer comprises a plurality of light-emitting units, the plurality of light-emitting units are arranged in an array, and at least one first light-transmitting opening is located between two adjacent light-emitting units in a same row or column;
the plurality of light-emitting units are arranged in an array along a first direction and a second direction, the first light-transmitting opening comprises a first light-transmitting sub-opening and a second light-transmitting sub-opening, a length of the first light-transmitting sub-opening in the first direction is greater than a length thereof in the second direction, and a length of the second light-transmitting sub-opening in the second direction is greater than a length thereof in the first direction;
wherein the plurality of light-emitting units comprise a plurality of first light-emitting units and a plurality of second light-emitting units,
the plurality of the first light-emitting units and the plurality of the second light-emitting units are arranged in rows along the first direction, and the second light-transmitting sub-opening is located between the first light-emitting unit and the second light-emitting unit adjacent to each other along the first direction,
or, the plurality of first light-emitting units and the plurality of second light-emitting units are arranged in columns along the second direction, and the first light-transmitting sub-opening is located between the first light-emitting unit and the second light-emitting unit adjacent to each other along the second direction,
or, the plurality of the first light-emitting units and the plurality of the second light-emitting units are arranged in rows along the first direction, and the second light-transmitting sub-opening is located between the first light-emitting unit and the second light-emitting unit adjacent to each other along the first direction, and the plurality of first light-emitting units and the plurality of second light-emitting units are arranged in columns along the second direction, and the first light-transmitting sub-opening is located between the first light-emitting unit and the second light-emitting unit adjacent to each other along the second direction.

8. The display panel of claim 7, wherein the plurality of light-emitting units further comprise a plurality of third light-emitting units, the plurality of first light-emitting units and the plurality of second light-emitting units are alternately arranged along the first direction to form a first pixel column, the plurality of third light-emitting units are arranged along the first direction to form a second pixel column, and the first pixel column and the second pixel column are alternately arranged along the second direction;
the orthographic projection of the first light-transmitting opening on the substrate is located between orthographic projections of the first light-emitting unit and the second light-emitting unit adjacent to each other along the first direction, or the second direction, or the first direction and the second direction on the substrate;
one of the first light-emitting unit and the second light-emitting unit is a red light-emitting unit, and the other is a blue light-emitting unit;
the third light-emitting unit in the second pixel column is correspondingly located between the first light-emitting unit and the second light-emitting unit adjacent to each other in the first pixel column; and
two of the plurality of second light-emitting units and two of the plurality of first light-emitting units are arranged on a peripheral side of the third light-emitting unit, and the two first light-emitting units and the two second light-emitting units are alternately arranged on the peripheral side of the third light-emitting unit.

9. The display panel of claim 1, wherein a second communication hole is arranged through the insulating protective layer, the light-transmitting conductive layer is electrically connected to the isolation structure through the second communication hole, and the first light-transmitting opening and the second communication hole are arranged at intervals on a peripheral side of the isolation opening;
an orthographic projection of the second communication hole on the substrate is located within a range of an orthographic projection of the isolation structure on the substrate; and
at least three first light-transmitting openings and one second communication hole are arranged on the peripheral side of a same isolation opening.

10. The display panel of claim 1, wherein the insulating protective layer is provided with a first opening, the light-transmitting conductive layer has a mesh structure and has a second opening, and an orthographic projection of the second opening on the substrate at least partially overlaps with an orthographic projection of the first opening on the substrate;
the orthographic projection of the first opening on the substrate is located within the orthographic projection of the second opening on the substrate;
the display panel further comprises a pixel defining layer, the pixel defining layer is located on a side of the light-transmitting conductive layer facing the substrate, the pixel defining layer comprises a pixel defining portion and a pixel opening provided in the pixel defining portion, and an orthographic projection of the pixel opening on the substrate at least partially overlaps with the orthographic projection of the second opening on the substrate;
the pixel defining layer is reused as the insulating protective layer; and the orthographic projection of the pixel opening on the substrate is located within the orthographic projection of the second opening on the substrate;
the orthographic projection of the pixel opening on the substrate is located within the orthographic projection of the first opening on the substrate; and
the orthographic projection of the pixel opening on the substrate is located within an orthographic projection of the isolation opening on the substrate.

11. The display panel of claim 1, wherein the light-transmitting conductive layer comprises a plurality of light-transmitting conductive portions arranged independently from each other, the insulating protective layer further comprises a plurality of third communication holes provided therethrough, and the light-transmitting conductive portions are electrically connected to the isolation structure through the third communication holes.

12. The display panel of claim 11, wherein the light-transmitting conductive portions each comprise a shielding portion and a connecting portion, an orthographic projection of the shielding portion on the substrate at least partially overlaps with the orthographic projection of the first light-transmitting opening on the substrate, and the isolation structure and the connecting portion are via connected through the third communication hole;
an area of the orthographic projection of the shielding portion on the substrate is greater than an area of an orthographic projection of the connecting portion on the substrate; and
the orthographic projection of the first light-transmitting opening on the substrate is located within a range of the orthographic projection of the shielding portion on the substrate.

13. The display panel of claim 12, wherein the light-emitting unit comprises a first light-emitting unit and a second light-emitting unit alternately arranged along a first direction and a second direction, and the shielding portion is located between the first light-emitting unit and the second light-emitting unit.

14. The display panel of claim 13, wherein the shielding portion is located between the first light-emitting unit and the second light-emitting unit adjacent to each other along the first direction or the second direction;
there is a first reference connection line between centers of an orthographic projection of the third communication hole on the substrate and the first light-emitting unit or the second light-emitting unit closest thereto, and the first reference connection line intersects the first direction and the second direction in a same plane;
an angle between the first reference connection line and the first direction or the second direction ranges from 30 degrees to 60 degrees;
the angle between the first reference connection line and the first direction or the second direction is 45 degrees;
there is a second reference connection line between centers of the orthographic projection of the third communication hole on the substrate and the orthographic projection of the shielding portion on the substrate, and the second reference connection line intersects the first direction and the second direction in a same plane;
an angle between the second reference connection line and the first direction or the second direction ranges from 30 degrees to 60 degrees;
the angle between the second reference connection line and the first direction or the second direction is 45 degrees;
the third communication hole is located between the first light-emitting unit and the second light-emitting unit; and
an orthographic projection of the isolation structure on the substrate covers an orthographic projection of the third communication hole on the substrate.

15. The display panel of claim 1, wherein the display panel comprises a display region and a non-display region adjacent to the display region, the light-transmitting conductive layer comprises a first conductive portion located in the display region and a second conductive portion located in the non-display region, and the first conductive portion is electrically connected to the isolation structure;
the first conductive portion and the second conductive portion are connected to each other;
the substrate is provided with a signal line located in the non-display region, and an orthographic projection of the signal line on the substrate at least partially overlaps with an orthographic projection of the second conductive portion on the substrate; and
the insulating protective layer covers the light-transmitting conductive layer in the display region and the non-display region.

16. The display panel of claim 15, wherein the display panel further comprises a dam located in the non-display region and arranged on one side of the substrate, and at least part of the second conductive portion is arranged on a side of the dam facing the display region;
the second conductive portion comprises a first segment located on the side of the dam facing the display region and a second segment covering at least part of a surface of the dam, and the second segment and the first segment are connected to each other;
the second segment covers a side surface on the side of the dam facing the display region, or the second segment covers the side surface on the side of the dam facing the display region and a top surface of the dam facing away from the substrate; and
the non-display region comprises a hole region, and the dam and the display region are arranged around the hole region.

17. The display panel of claim 16, further comprising a pixel defining layer located on a side of the light-transmitting conductive layer facing the substrate, the pixel defining layer comprising a pixel defining portion located in the display region and a pad portion located in the non-display region, the pad portion being located on a side of the second conductive portion facing the substrate;
the pad portion covers at least part of the dam; and
the display panel further comprises a touch layer located on a side of the isolation structure away from the substrate.

18. A display panel, comprising:
a substrate;
a light-transmitting conductive layer arranged on one side of the substrate, the light-transmitting conductive layer having a mesh structure and having a second opening;
an isolation structure arranged on a side of the light-transmitting conductive layer facing away from the substrate, the isolation structure enclosing and forming an isolation opening and a first light-transmitting opening, and an orthographic projection of the isolation opening on the substrate being located within an orthographic projection of the second opening on the substrate; and
a light-emitting layer comprising a light-emitting unit located in the isolation opening;
wherein an orthographic projection of the first light-transmitting opening on the substrate is located within an orthographic projection of the light-transmitting conductive layer on the substrate, and the isolation structure is electrically connected to the light-transmitting conductive layer.

19. The display panel of claim 18, further comprising an insulating protective layer arranged on the side of the light-transmitting conductive layer facing away from the substrate, a first opening being arranged through the insulating protective layer, and the orthographic projection of the isolation opening on the substrate at least partially overlapping with an orthographic projection of the first opening on the substrate.

20. A display panel, comprising:
a substrate;
a light-transmitting conductive layer arranged on one side of the substrate, the light-transmitting conductive layer comprises a plurality of light-transmitting conductive portions arranged independently from each other;
an isolation structure arranged on a side of the light-transmitting conductive layer facing away from the substrate, the isolation structure enclosing and forming an isolation opening and a first light-transmitting opening;
a light-emitting layer comprising a light-emitting unit located in the isolation opening;
wherein an orthographic projection of the first light-transmitting opening on the substrate is located within an orthographic projection of one of the plurality of light-transmitting conductive portions on the substrate, and the isolation structure is electrically connected to one of the plurality of light-transmitting conductive portions.
